(19) United States
(12) Patent Application Publication
(10) Pub. No.: US 2012/0032264 A1
(43) Pub. Date: Feb. 9, 2012

(54) High density semiconductor latch

(76) Inventors: Fabio Alessio Marino, (US); Paolo Menegoli, (US)

(21) Appl. No.: 12/927,675

(22) Filed: Nov. 22, 2010

Related U.S. Application Data
(60) Provisional application No. 61/401,073, filed on Aug. 9, 2010.

(51) Int. Cl. H01L 27/12; H01L 21/84

(52) U.S. Cl. 257/350; 438/154; 257/E27.112; 257/E21.703

(57) ABSTRACT

A novel semiconductor latch is presented. The semiconductor structure is simple and has a reduced number of semiconductor junctions. It offers the advantage of being very small in area, very fast and very efficient. The current conductivity in the structures of the latch circuit is controlled by the gates voltage by means of depleting and enhancing the areas under the gate oxide. The signal isolation is obtained mainly by the carrier depletion of the channel region. By having a reduced number of semiconductor junctions, the intrinsic current leakage can be very small. This latch is the elementary component for volatile memory and logic elements based on this principle.

### RELATED APPLICATION DATA

The present application claims priority from U.S. Provisional Patent Application No. 61/401,073 for “High Density Semiconductor Latch” filed on Aug. 9, 2010.

### BACKGROUND OF THE INVENTION

1. Field of the Invention

The present invention is in the field of semiconductor structures. The present invention further relates to semiconductor latches and digital circuits. The present invention further relates to the field of volatile memory cells. The implementation is not limited to a specific technology, and applies to either the invention as an individual component or to inclusion of the present invention within larger systems which may be combined into larger integrated circuits.

2. Brief Description of Related Art

The semiconductor latch is one of the most important components for larger digital integrated circuits and in particular for Flip Flops and volatile memories like static and dynamic random access memories. The complementary CMOS components used in current integrated circuit process technologies have undergone a continuous shrinking of the silicon area needed for elementary components like the CMOS latch; however being the latch one of the most commonly utilized digital circuits from which many others have derived, the need to further improve on its general performance while reducing its cost is a necessity that poses a significant challenge.

Generally the most utilized prior art of CMOS digital latches comprises two inverters cross coupled so that the input of one is connected to the output terminal of the other and vice-versa. Due to the intrinsic positive feedback generated by the circuit, when the voltage polarity at one input terminal of one inverter is high, the voltage polarity at the input terminal of the second inverter is low and vice versa. The dynamic characteristic of the signal toggling are very important to establish the latch efficiency and speed. This is especially true when reading and writing data in Static Random Access Memory (SRAM) cells.

Large arrays of CMOS latches have been widely used for SRAM banks to efficiently store data as long as the power supply of the memory is present. Much larger arrays of memory cells have been utilized in DRAM memories, but typically they do not employ latches; rather small capacitors that have to be regularly refreshed to retain the data.

Each bit in an SRAM is stored on four transistors that form two cross-coupled inverters. Two additional access transistors serve to control the access to a storage cell during read and write operations. A typical SRAM uses six MOSFETs devices to store each memory bit. In addition to such 6T SRAM, other kinds of SRAM chips use 8, 10, or more transistors per individual cell. Examples of these SRAM memories with more than 6 transistors for cell, can be found in the prior art Houston (U.S. Pat. No. 7,742,326) and Chang et al. (US 2007/0242513). This multi-transistor approach is sometimes used to implement more than one (read and/or write) port, which may be useful in certain types of video memory and register files implemented with multi ported SRAM circuitry.

Generally, the fewer transistors needed per cell, the smaller each cell can be. Since the cost of processing a silicon wafer is relatively fixed, using smaller cells and so packing more bits on one wafer reduces the cost per bit of the memory.

Memory cells that use fewer than 6 transistors are possible, but such 3T or 1T cells are DRAM rather than SRAM (even the so-called 1T-SRAM), since they require periodic refresh of the stored data.

SRAM is more expensive, but faster and significantly less power hungry (especially when idle) than DRAM. It is therefore used where either bandwidth or low power, or both, are principal considerations. SRAM is also easier to control (interface to) and generally more truly random access than modern types of DRAM. Due to a more complex internal structure, SRAM is less dense than DRAM and is therefore not used for high-capacity, low-cost applications such as the main memory in personal computers.

It is a purpose of the present invention to describe a novel CMOS structure of a semiconductor latch that offers the advantage of much higher density reducing silicon area and cost combined with improved performances in terms of speed and power dissipation.

### SUMMARY OF THE INVENTION

The present invention describes a semiconductor latch built using a single semiconductor structure of minimum dimensions. This structure exploits the same active region of a single MOSFET for multiple components, by adding one or more Metal/Oxide layers. This concept is very important and will become clearer upon consideration of the following detailed description of the invention. The present invention makes use of inverter structures described in the regular patent application “High Density Semiconductor Inverter” (U.S. Ser. No. 12/925,535) by the same applicants, as illustrated in FIG. 2.

As can be seen, the structure of FIG. 2 is formed by stacking the two inverters 12 and 13. This is done in a way that the output 22 of the inverter 12 forms the gate of the inverter structure 13. The output 20 of the second inverter 13 is coupled to the gate electrode 14 in the third dimension, in order to close the positive feedback loop of the two inverters.

In order to better understand the operation of this structure, let us consider the case in which the n-terminal 25 is connected to the ground and the p-terminal 16 is connected to a generic supply voltage V_{DD}. In such situation, when the voltage of the gate terminal 14 goes to V_{DD}, the depletion region in the p-substrate 17 under the gate-oxide 15 widens. If the thickness t_{S} of the metal layer 22 is thin enough, for V_{G}=Vₜₚ (threshold voltage) the depletion region width x_{d} is greater than t_{S}, and the metal 22 is therefore isolated from the p-terminal 16. On the other hand, at the same time, electrons start to accumulate under the gate oxide 15 in the n-side region 24. Consequently, the metallic terminal 22 gets connected with the n-terminal 25 and the voltage of the terminal 22 goes to 0V.

At the same time, since the metal layer 22 represents the gate of the structure 13, the depletion region in the n-substrate 24 under the second gate-oxide 19 widens. If the thickness t_{S2} of the metal layer 20 is thin enough, for V_{G}=Vₜₙ (threshold voltage) the depletion region width x_{d2} is greater than t_{S2}, and the metal 20 is therefore isolated from the n-terminal 25. However, simultaneously holes start to accumulate under the gate oxide 19 in the p-side region 17, and as a consequence, the metallic terminal 20 gets connected with the p-terminal 16 and the voltage of the terminal 20 goes to V_{DD}.

By increasing the voltage of the gate terminal 14, the exact opposite mechanism occurs: holes start to accumulate under the gate oxide 15 on the p-side 17 and the n-substrate 24 depletes. Consequently the metal region 22 goes to the supply voltage V_{DD}. This leads to the accumulation of electrons under the gate oxide 19 on the n-side 24 and to the local depletion of the p-substrate 17. Consequently the voltage of the metal region 20 goes to 0V.

Therefore the illustrated field effect device behaves as an active latch with a bi-stable characteristic.

In order to better decouple the action of the gate terminal 14 from the inverter 13, two isolating regions 18 and 23 are presents.

The same isolation effect can be achieved as illustrated in FIG. 3, where the shape of the two isolating regions 34 and 39 and the shape of the metal region 38 optimize the gate effect of the metal region 38 on the second inverter 29.

Another means of stacking the inverter structures is illustrated in FIG. 4. As it can be seen, in this structure, the second inverter 45 is placed upside down with respect to the first inverter 44.

In all these structures, the two inverters can be built, by anybody skilled in the art, in one of the many variants taught in the patent application “High Density Semiconductor Inverter” (U.S. Ser. No. 12/925,535), or mixing different variants.

The memory element disclosed can be used to built an SRAM memory simply by adding one or more access transistors to the structure. This can be done in different ways; one means is illustrated in FIG. 5, where an access transistor 60 is formed on the top of the latch structure. The body of this device is made in silicon p-doped in order to preserve a high mobility in the access device. The gate 61 and the bit line region 56 represent respectively the source and the drain of the access transistor 60 and they can be made in metal or semiconductor based on the process technology available.

A similar result can be obtained as illustrated in FIG. 6, where an insulating region 75 has been added below the body of the access transistor 80.

The access transistor can be built also with a vertical approach, and more specifically can be formed above the gate area of the first inverter structure as illustrated in FIG. 7.

The carrier transport in the access transistor can be also enhanced using a double gate FET.

In FIG. 8 is reported the preferred embodiment of the invention. As it can be seen, this structure is similar to the one shown in FIG. 7, with the difference that the upper part of region 97 is replaced by a n-type region 125 and a p-type region 117. The same hold for region 110, which is replaced with the semiconductor regions 120 and 119. Furthermore, two bump are present in the center of the dielectric layers 114 and 121 in order to decrease the leakage currents inside the device.

FIG. 9 is showing the simulation results of the preferred embodiment of the invention compared with the simulation results obtained with a standard CMOS technology.

As it can appear evident to any person skilled in the art, different possible variations can be obtained mixing the different versions illustrated. Furthermore the present invention can also be realized in SOI (Semiconductor On Insulator) or bulk technology.

In the case of CMOS bulk process technology, for example, the process steps required to build the structure of FIG. 8, which represents the preferred embodiment of the invention, can be summarized as follows. Starting from a p-doped (boron doped) wafer, an n-well is obtained with an n-type (arsenic or phosphor) implant. Thereafter, two more wells, one n-type and one p-type, are created in the substrate and in the previously described n-well, respectively. These two wells will form regions 126 and 116 in the structure of FIG. 8. A silicon etching and an oxide deposition will follow in order to form the BOX oxide region 121.

Regions 119 and 120 can be then grown above region 111, using a silicon epitaxial growth technique followed by two doping implants. The gate oxide 122 can be successively formed with thermal growth techniques. A small bump is created above the gate oxide layer 122, with a deposition and with an oxide etch process step. Thereafter, on the top of the dielectric layer 122, the two insulating layers 124 and 118, and the metallic layer 123 are formed.

Regions 125 and 117 can be then grown above region 123, 124, and 118, using a silicon epitaxial growth technique followed by two doping implants. The gate oxide 114 can be then formed with thermal growth techniques. Also in this case, a small bump is created above the gate oxide layer 114. Thereafter, on the top of the dielectric layer 114, an n-type poly-silicon layer 128 is deposited.

Thereafter, above the poly-silicon layer 128, the p-type 113 and the n-type 112 poly-silicon layers are deposited. The lateral gate oxide 129 can be then formed with a poly-silicon etch and with a thermal growth (or deposition) process step. The lateral gate 130 can be finally formed.

Successively the contacts 127 and 115 can be formed using two more doping implants and one metal deposition. These two heavily doped regions and their respective metal contacts can be placed laterally or elsewhere.

It is important to notice that under the two contacts 127 and 115 of FIG. 8, heavily doped regions must be formed in order to reduce the contacts resistivity. These two regions have been omitted in all the drawings for simplicity, but their presence is obvious to a person skilled in the art.

It is therefore an object of the invention to increase the packing density and to reduce the device wiring capacitances by adding logic functionality to the single transistor without adding substantially to the transistor silicon area. It is therefore a further object of the invention to increase the speed of reading and writing of the memory element by reducing the number of junctions and eliminating the parasitic body diodes.

As is clear to those skilled in the art, this basic structure can be implemented in many specific ways, and the above descriptions are not meant to designate a specific implementation.

### BRIEF DESCRIPTION OF THE DRAWINGS

The features, objects, and advantages of the present invention will become apparent upon consideration of the following detailed description of the invention when read in conjunction with the drawing in which:

FIG. 1 is a cross section view of a conventional latch (prior art).

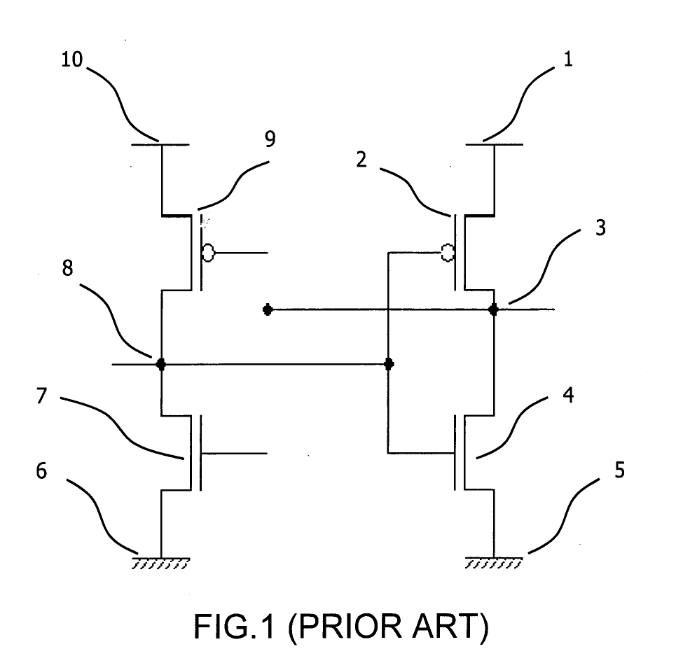

FIG. 2 is a cross section view of a first embodiment of the invention.

FIG. 3 is a cross section view of a second embodiment of the invention.

FIG. 4 is a cross section view of a third embodiment of the invention.

FIG. 5 is a cross section view of a fourth embodiment of the invention.

FIG. 6 is a cross section view of a fifth embodiment of the invention.

FIG. 7 is a cross section view of a sixth embodiment of the invention.

FIG. 8 is a cross section view of a preferred embodiment of the invention.

FIG. 9 illustrates the simulation results of the preferred embodiment of the invention compared with the simulation results obtained with a memory cell built using a conventional CMOS technology.

### DESCRIPTION OF THE PREFERRED EMBODIMENT

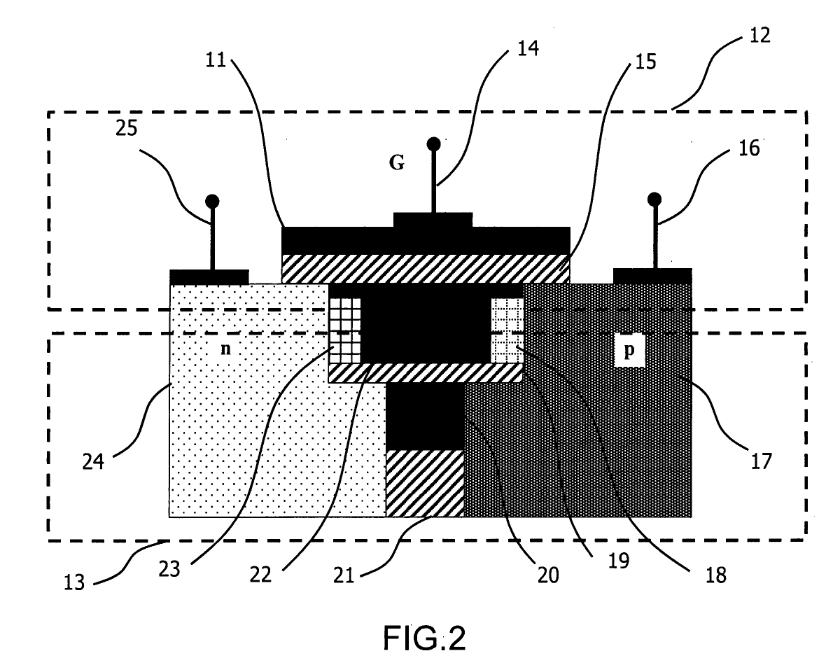

### A FIG. 2

FIG. 2 is showing the cross-section view of the first embodiment of the invention. The n-type region 24 and the metal region 22 define a first n-type transistor. The p-type region 17 and the metal region 22 define a second p-type transistor. The n-type region 24 and the metal region 20 define a third n-type transistor. The p-type region 17 and the metal region 20 define a fourth p-type transistor. The region 24 corresponds to the source of both n-type transistors. The region 17 corresponds to the source of both p-type transistors. The metal region 22 corresponds to the drain of both the first and the second transistors. The metal region 20 corresponds to the drain of both the third and the fourth transistors.

The gate electrode 14, which may be built in poly-silicon or metal, forms the gate of both the first and the second transistors. The output of the first inverter 12 composed by the first two transistors, is the metal layer 22 and this constitutes also the gate of the second inverter 153 composed by the third and the fourth transistor.

A box oxide 21 is present under the metal region 20 to electrically isolate the source of the n-type transistors from the source of the p-type transistors. Above the metal region 20 an oxide layer 19 is present and extends over the metal region, in the regions 24 and 17. Above the oxide layer 19, the metal layer 22 is present.

Above the metal region 22 an oxide layer 15 is present and it extends beyond the metal region, above the regions 24 and 17. Above the oxide layer 15, the gate layer 11 is present.

In order to understand the operation of this semiconductor device, let us consider the case in which the n-terminal 25 is connected to the ground and the p-terminal 16 is connected to a generic supply voltage V_{DD}. In such situation, when the voltage of the gate terminal 14 goes to V_{DD}, the depletion region in the p-substrate 17 under the gate-oxide 15 widens. If the thickness t_{S} of the metal layer 22 is thin enough, for V_{G}=Vₜₚ (threshold voltage) the depletion region width x_{d} is greater than t_{S}, and the metal 22 is therefore isolated from the p-terminal 16. On the other hand, at the same time, electrons start to accumulate under the gate oxide 15 in the n-side region 24. Consequently, the metallic terminal 22 gets connected with the n-terminal 25 and the voltage of the terminal 22 goes to 0V.

At the same time, since the metal layer 22 represents the gate of the structure 13, the depletion region in the n-substrate 24 under the second gate-oxide 19 widens. If the thickness t_{S2} of the metal layer 20 is thin enough, for V_{G}=Vₜₙ (threshold voltage) the depletion region width x_{d2} is greater than t_{S2}, and the metal 20 is therefore isolated from the n-terminal 25. At the same time, holes start to accumulate under the gate oxide 19 in the p-side region 17 and as consequence, the metallic terminal 20 gets connected with the p-terminal 16 and the voltage of the terminal 20 goes to V_{DD}.

By increasing the voltage of the gate terminal 14, the exact opposite mechanism occurs: holes start to accumulate under the gate oxide 15 on the p-side 17 and the n-substrate 24 depletes. Consequently the metal region 22 goes to the supply voltage V_{DD}. This leads to the accumulation of electrons under the gate oxide 19 on the n-side 24 and to the local depletion of the p-substrate 17. Consequently the metal region 20 goes to 0V.

Therefore the illustrated field effect device behaves as an active latch with a bi-stable characteristic.

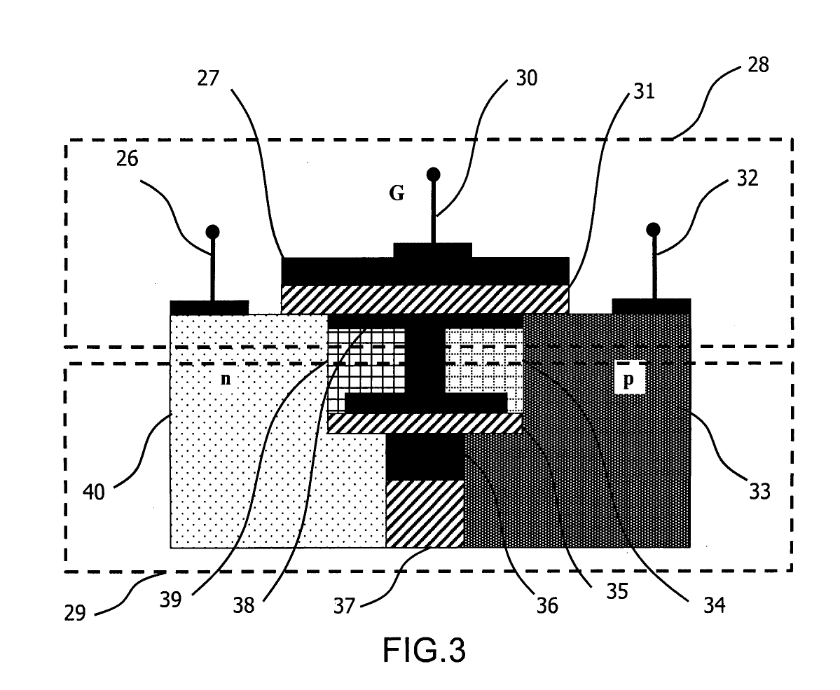

### B FIG. 3

The drawing of FIG. 3 shows a cross section view of the second embodiment of the semiconductor latch. The only difference with FIG. 2 is that the upper part of the metal region 38 is a T shape in order to decrease the capacitive coupling between this region and the side regions 33 and 40.

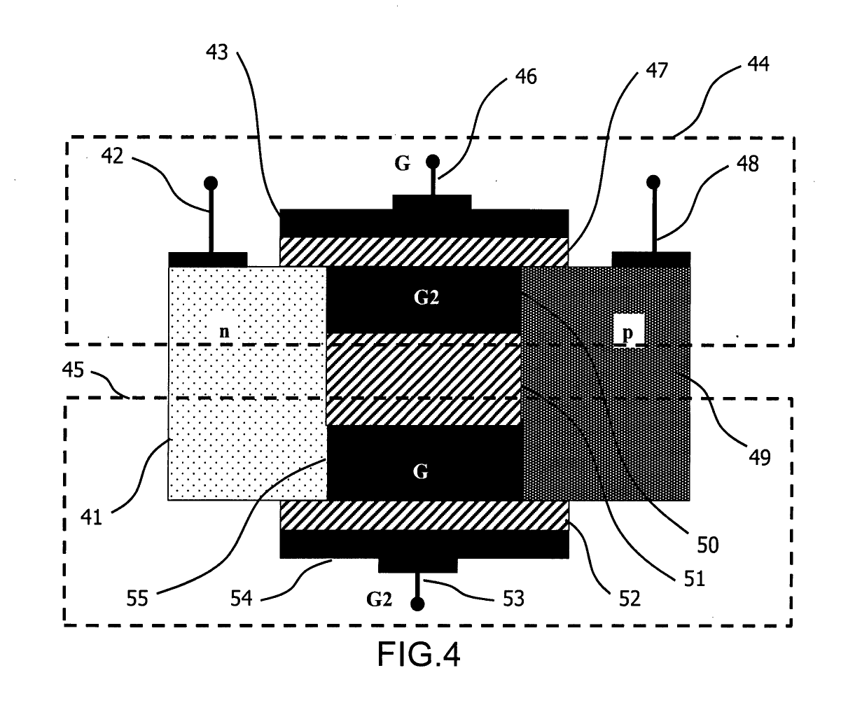

### C FIG. 4

FIG. 4 illustrates a third embodiment of the invention, where the second inverter 45 is upside down with respect to the first inverter 44. In this case the gate 46 of the first inverter 44 is coupled to the output 55 of the second inverter 45 in the third spatial dimension and the gate 53 of the second inverter 45 is coupled to the output 50 of the first inverter 44 in the third dimension but in opposite direction with respect to the other.

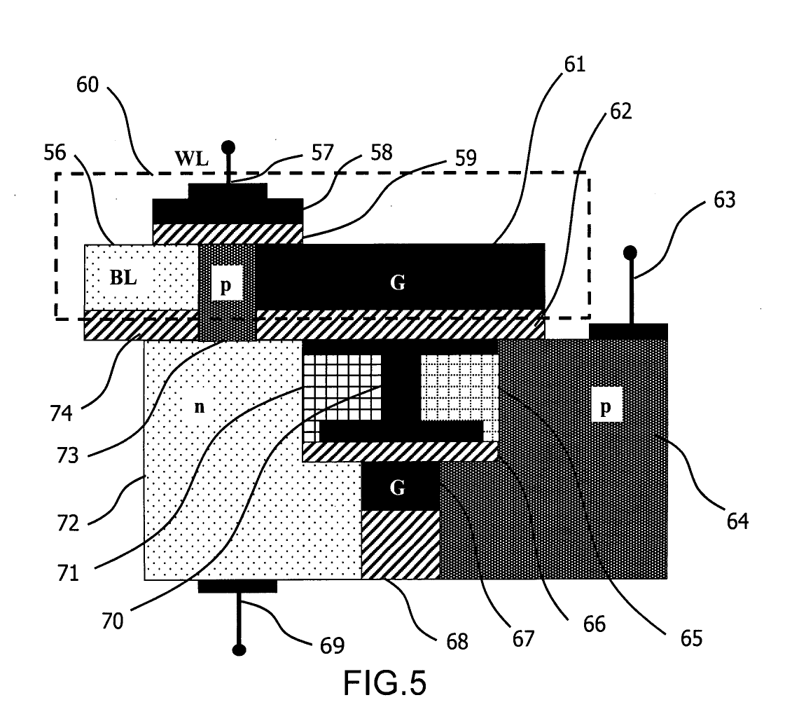

### D FIG. 5

FIG. 5 is depicting the cross-section view of a fourth embodiment of the invention. This structure is similar to FIG. 3, but an access transistor 60 is added to obtain an SRAM cell. The body 73 of the access transistor is made in silicon in order to preserve the high carrier mobility, whereas the Bit Line region 56 and the region 61 can be made in metal or semiconductor depending on the technology available. The access transistor can be a depletion or enhancement mode device.

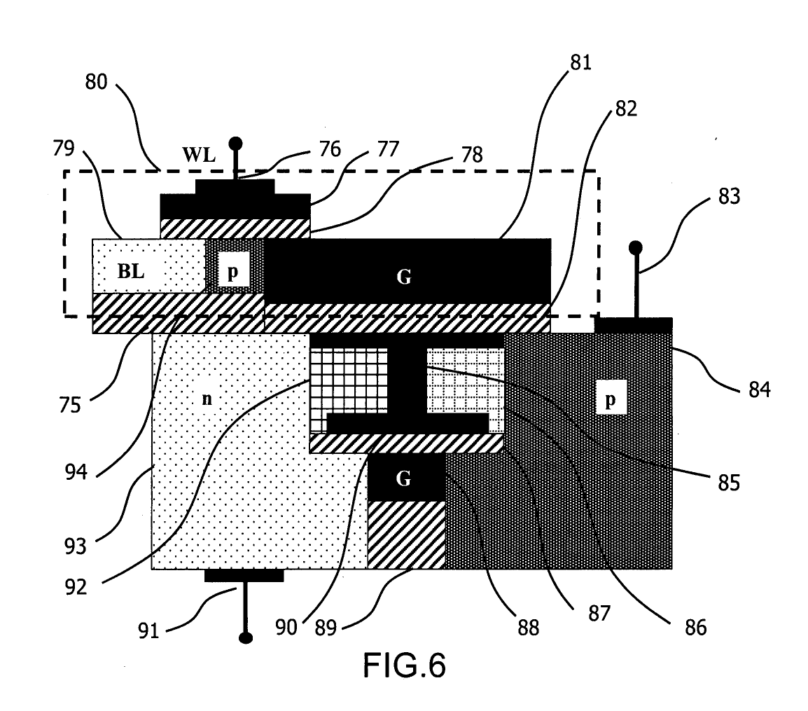

### E FIG. 6

FIG. 6 is showing the cross-section view of a fifth embodiment of the invention.

This structure is similar to one depicted in FIG. 5, with the exception that an insulating region 75 is formed between the region 93 and the body 94 of the access transistor 80.

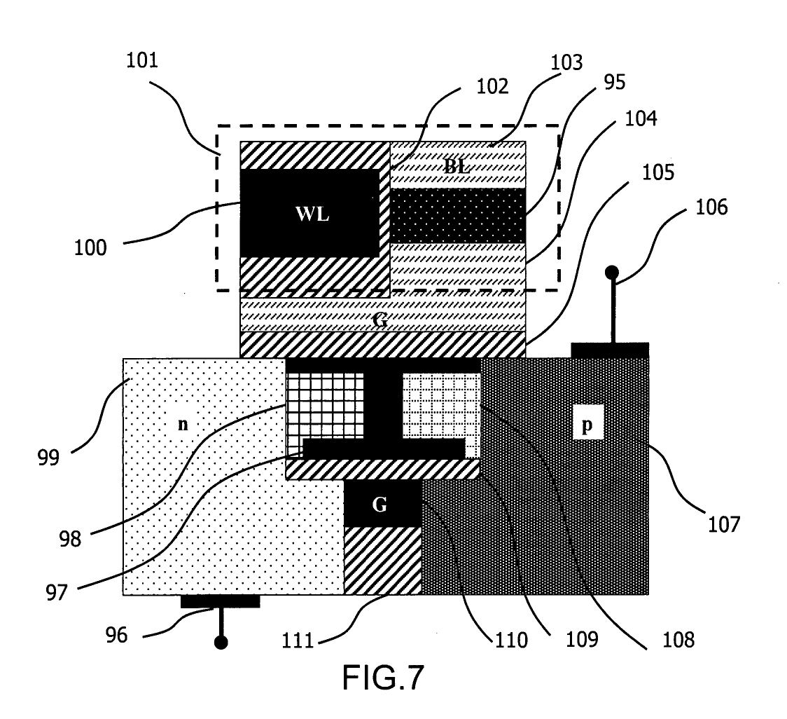

### F FIG. 7

FIG. 7 is showing the cross-section view of a sixth embodiment of the invention. This structure is similar to one depicted in FIG. 6, with the difference that in this case the access transistor 101 is vertical and it is formed above the gate 104 saving silicon area.

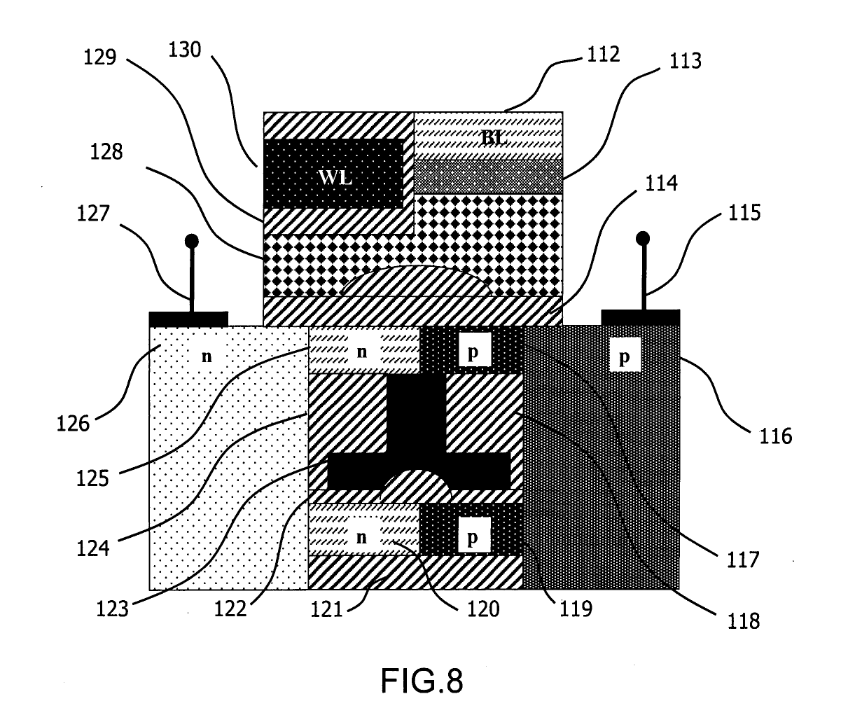

### G FIG. 8

FIG. 8 is showing the cross-section view of the preferred embodiment of the invention. As it can be seen, this structure is similar to the one shown in FIG. 7, with the difference that the upper part of region 97 is replaced by an n-type region 125 and a p-type region 117. The same holds for region 110, which is replaced by the semiconductor regions 120 and 119. Furthermore, two bumps are present in the center of the dielectric layers 114 and 121 in order to decrease the static leakage currents in the device.

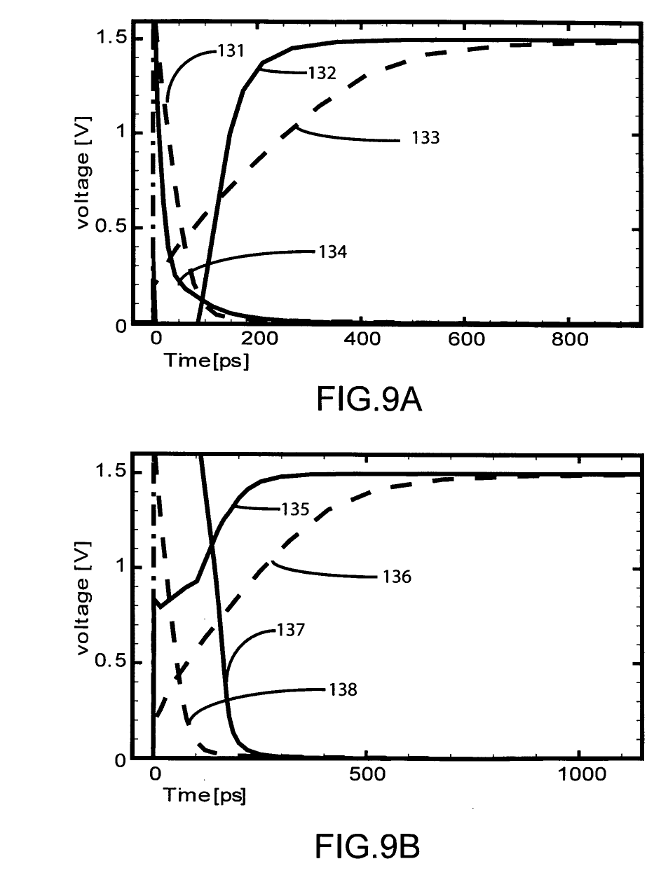

### H FIG. 9

FIG. 9 is showing the simulation results of the preferred embodiment of the invention compared with the simulation results obtained with a standard 6T SRAM cell built in CMOS technology. Waveforms 131 and 133 represent the voltages of the two internal nodes of a classical CMOS SRAM, whereas waveforms 132 and 134 are the voltages of the two internal nodes of the presented invention, in the case in which in the cell has stored a “1” and we are writing a “0”. The waveforms 136 and 138 represent the voltages of the two internal nodes of a classical CMOS SRAM, whereas waveforms 135 and 137 are the voltages of the two internal nodes of the presented invention, in the case in which in the cell stores a “0” and we are writing a “1”.

As it can be seen, the present invention allows the reduction by a factor of 2 the time requested from the memory cell to overwrite the stored data, leading to a great improvement of the writing performance with respect to the classical CMOS technology.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed is:

1. An efficient memory cell structure comprising:
a first inverter comprising a first field effect transistor of a first conductivity type, and a second field effect transistor of a second conductivity type;
a second inverter comprising a third field effect transistor of said first conductivity type, and a fourth field effect transistor of said second conductivity type;
wherein said first and second inverters are stacked one above the other;
wherein the sources of said first and third field effect transistors are formed in a single first source region coupled to a first supply voltage;
wherein the sources of said second and fourth field effect transistors are formed in a single second source region coupled to a second supply voltage;
wherein the drains of said first and second field effect transistors are formed above the gates of said third and fourth field effect transistors;
wherein said drains of said first and second field effect transistors are directly coupled together and to said gates of said third and fourth field effect transistors;
wherein the drains of said third and fourth field effect transistors are directly coupled together and to the gates of said first and second field effect transistors;

2. The structure of claim 1 wherein said regions of said memory cell are made from at least one of the materials belonging to the group comprising of semiconductor, dielectric and metal.

3. The structure of claim 1 wherein at least one of said first and second source regions is divided in two separated regions of same or different materials directly coupled together.

4. The structure of claim 1 wherein at least one of said first and second inverters has the drains of both field effect transistors made of the same material, and formed in the same region.

5. The structure of claim 1 wherein at least one of said first and second inverters has the gates of both field effect transistors made of the same material, and formed in the same region.

6. The structure of claim 1 wherein said memory cell is comprising n-well and p-well regions below said third and fourth transistors.

7. The structure of claim 1 wherein said memory cell is formed within silicon on insulator substrate.

8. The structure of claim 1 wherein one of said first and second inverters is rotated of 180 degrees with respect to the other.

9. The structure of claim 1 wherein said memory cell is comprising at least one access field effect transistor coupled to said memory cell.

10. The structure of claim 1 wherein said memory cell is comprising at least one access field effect transistor coupled to said memory cell, and
wherein at least one of said access field effect transistors is formed above at least one of said gates of said first and second field effect transistors.

11. A method for generating an efficient memory cell comprising:
forming a first inverter comprising a first field effect transistor of a first conductivity type, and a second field effect transistor of a second conductivity type;
forming a second inverter comprising a third field effect transistor of said first conductivity type, and a fourth field effect transistor of said second conductivity type;
wherein said first and second inverters are stacked one above the other;
wherein the sources of said first and third field effect transistors are formed in a single first source region coupled to a first supply voltage;
wherein the sources of said second and fourth field effect transistors are formed in a single second source region coupled to a second supply voltage;
wherein the drains of said first and second field effect transistors are formed above the gates of said third and fourth field effect transistors;
wherein said drains of said first and second field effect transistors are directly coupled together and to said gates of said third and fourth field effect transistors;
wherein the drains of said third and fourth field effect transistors are directly coupled together and to the gates of said first and second field effect transistors;

12. The method of claim 11 wherein the regions of said memory cell are made from at least one of the materials belonging to the group comprising of semiconductor, dielectric and metal.

13. The method of claim 11 wherein at least one of said first and second source regions is divided in two separated regions of same or different materials directly coupled together.

14. The method of claim 11 wherein at least one of said first and second inverters has the drains of both field effect transistors made of the same material, and formed in the same region.

15. The method of claim 11 wherein at least one of said first and second inverters has the gates of both field effect transistors made of the same material, and formed in the same region.

16. The method of claim 11 wherein said memory cell is comprising n-well and p-well regions below said third and fourth transistors.

17. The method of claim 11 wherein said memory cell is formed within silicon on insulator substrate.

18. The method of claim 11 wherein one of said first and second inverters is rotated 180 degrees with respect to the other.

19. The method of claim 11 wherein said memory cell is comprising at least one access field effect transistor coupled to said memory cell.

20. The method of claim 11 wherein said memory cell is comprising at least one access field effect transistor coupled to said memory cell, and
wherein at least one of said access field effect transistors is formed above at least one of said gates of said first and second field effect transistors.
